(19) United States
(12) Patent Application Publication
(10) Pub. No.: US 2025/0278024 A1
(43) Pub. Date: Sep. 4, 2025

(54) PHOTOSENSITIVE ELEMENT, METHOD FOR FORMING RESIST PATTERN, AND METHOD FOR MANUFACTURING PRINTED WIRING BOARD

(71) Applicant: Resonac Corporation, Tokyo (JP)

(72) Inventors: Yosuke KAGUCHI, Tokyo (JP); Kensuke YOSHIHARA, Tokyo (JP); Natsuki TODA, Tokyo (JP); Hiroshi ONO, Tokyo (JP)

(21) Appl. No.: 18/858,202

(22) PCT Filed: Aug. 30, 2023
(86) PCT No.: PCT/JP2023/031634

§ 371 Date: Oct. 18, 2024

(30) Foreign Application Priority Data
Nov. 28, 2022 (WO) PCT/JP2022/043813

(51) Int. Cl. G03F 7/09

(52) U.S. Cl. CPC G03F 7/094

(57) ABSTRACT

One aspect of the present disclosure relates to a photosensitive element including a support film containing a lubricant and a photosensitive layer formed on a first surface of the support film, in which a number of lubricants having a particle size of 1.0 μm or more contained in the first surface of the support film is 10 or less per 0.0225 mm².

### TECHNICAL FIELD

The present disclosure relates to a photosensitive element, a method for forming a resist pattern, and a method for producing a printed wiring board.

### BACKGROUND ART

In the field of production of printed wiring boards, photosensitive elements including a layer formed using a photosensitive resin composition (hereinafter, also referred to as “photosensitive layer”) on a support film have been widely used as resist materials used for an etching treatment, a plating treatment, or the like.

A printed wiring board is produced using a photosensitive element, for example, by the following procedure. That is, first, a photosensitive layer of a photosensitive element is laminated on a substrate for circuit formation such as a copper-clad laminate plate. Next, the photosensitive layer is exposed through a mask film or the like to form a photo-cured area. At this time, a support film is released before exposure or after exposure. Thereafter, an area other than the photo-cured area of the photosensitive layer is removed with a developing solution to form a resist pattern. Next, the substrate is subjected to an etching treatment or a plating treatment using the resist pattern as a resist to form a conductor pattern, and finally, the photo-cured area (resist pattern) of the photosensitive layer is released (removed).

As the support film used in the photosensitive element, a support film having a specific haze value, a support film having a specific lubricant particle size, and the like have been known (see, for example, Patent Literatures 1 and 2).

### CITATION LIST

### Patent Literature

Patent Literature 1: JP 2001-13681 A
Patent Literature 2: JP 2014-74764 A

### SUMMARY OF INVENTION

### Technical Problem

With an increase in resolution of circuit formation in recent years, problems arise in that resolution required for the photosensitive element and an exposure apparatus used for the circuit formation is increased, and resist defects (for example, defects such as resist chipping) derived from a lubricant or an aggregate thereof of the support film of the photosensitive element is increased.

An object of the present disclosure is to provide a photosensitive element with which occurrence of resist defects can be reduced, a method for forming a resist pattern using this photosensitive element, and a method for producing a printed wiring board.

### Solution to Problem

One aspect of the present disclosure relates to a photosensitive element, a method for forming a resist pattern, and a method for producing a printed wiring board described below.

[1] A photosensitive element including: a support film containing a lubricant; and a photosensitive layer formed on a first surface of the support film, in which a number of lubricants having a particle size of 1.0 μm or more contained in the first surface of the support film is 10 or less per 0.0225 mm².

[2] The photosensitive element described in [1], in which a number of lubricants having a particle size of less than 1.0 μm contained in the first surface is 10 to 160 per 0.0225 mm².

[3] The photosensitive element described in [1] or [2], in which a linear expansion coefficient of the support film at 80 to 115° C. is 30 to 170 ppm/° C., and a linear expansion coefficient of the support film at 115 to 130° C. is 30 to 170 ppm/° C.

[4] The photosensitive element described in any of [1] to [3], in which the support film has a polyester film and a lubricant layer disposed on at least one surface of the polyester film.

[5] The photosensitive element described in [4], in which the support film is a biaxially oriented polyester film with a three-layer structure.

[6] The photosensitive element described in any of [1] to [5], in which the support film does not contain a lubricant having a particle size of more than 3.0 μm.

[7]A method for forming a resist pattern, the method including: a lamination step of laminating the photosensitive element described in any of [1] to [6] on a substrate in order of the photosensitive layer and the support film; an exposure step of irradiating a predetermined part of the photosensitive layer with an active light ray through the support film to form a photo-cured area; and a development step of removing an area other than the photo-cured area in the photosensitive layer.

[8]A method for producing a printed wiring board, the method including a step of subjecting a substrate having a resist pattern formed by the method for forming a resist pattern described in [7] to an etching treatment or a plating treatment to form a conductor pattern.

### Advantageous Effects of Invention

According to the present disclosure, it is possible to provide a photosensitive element with which occurrence of resist defects can be reduced, a method for forming a resist pattern using this photosensitive element, and a method for producing a printed wiring board.

### BRIEF DESCRIPTION OF DRAWINGS

FIG. 1 is a schematic cross-sectional view illustrating an embodiment of a photosensitive element.

FIG. 2 is a view showing observation results of a surface of a support film.

### DESCRIPTION OF EMBODIMENTS

Hereinafter, embodiments for carrying out the present disclosure will be specifically described. However, the present disclosure is not limited to the following embodiments.

In the present specification, a numerical range that has been indicated by use of “to” indicates the range that includes the numerical values which are described before and after “to”, as the minimum value and the maximum value, respectively. The numerical range “A or more” means A and a range of more than A. The numerical range “A or less” means A and a range of less than A. In the numerical ranges that are described stepwise in the present specification, the upper limit value or the lower limit value of the numerical range of a certain stage can be arbitrarily combined with the upper limit value or the lower limit value of the numerical range of another stage. In a numerical range described in the present specification, the upper limit value or the lower limit value of the numerical range may be substituted by a value shown in Examples.

In the present specification, “A or B” may include either one of A and B, and may also include both of A and B. Materials listed as examples in the present specification can be used singly or in combinations of two or more kinds, unless otherwise specified. When a plurality of substances corresponding to each component exist in the composition, the content of each component in the composition means the total amount of the plurality of substances that exist in the composition, unless otherwise specified. The terms “layer” and “film” include a structure having a shape which is formed on a part, in addition to a structure having a shape which is formed on the whole surface, when the layer has been observed as a plan view. The term “step” includes not only an independent step but also a step by which an intended action of the step is achieved, even though the step cannot be clearly distinguished from other steps.

In the present specification, the term “(meth)acrylate” means at least one of acrylate and methacrylate corresponding thereto. The same applies to other analogous expressions such as “(meth)acrylic acid”. “EO” stands for ethylene oxide, and an “EO-modified” compound means a compound having an oxyethylene group. “PO” stands for propylene oxide, and a “PO-modified” compound means a compound having an oxypropylene group. The term “solid content” refers to a non-volatile content contained in a photosensitive resin composition excluding volatile substances such as water or a solvent, refers to a component remaining without volatile in drying of the resin composition, and also includes a component present in a liquid, syrupy, and waxy state at room temperature near 25° C.

### [Photosensitive Element]

A photosensitive element of the present embodiment includes: a support film containing a lubricant; and a photosensitive layer formed on a first surface of the support film, in which a number of lubricants having a particle size of 1.0 μm or more contained in the first surface of the support film is 10 or less per 0.0225 mm².

In the support film used in the photosensitive element, a lubricant is added for improving slidability. However, when the size of the lubricant contained in the support film becomes large, the lubricant may scatter light during exposure, which may cause resist defects. On the other hand, by reducing a lubricant having a particle size of 1.0 μm or more among lubricants contained in the surface of the support film in contact with the photosensitive layer, the number of resist defects can be reduced.

The lubricant is not particularly limited as long as it is a component that does not inhibit the light transparency of the support film and is used in the production of a polyester film, and may be an inorganic lubricant or an organic lubricant. Examples of the inorganic lubricant include inorganic particles containing, as an inorganic component, silica, calcium carbonate, alumina, aluminum silicate, mica, clay, talc, wollastonite, kaolin, zinc oxide, barium sulfate, calcium phosphate, calcium, magnesium, barium, zinc, manganese, or the like. Examples of the organic lubricant include crosslinked polymers such as polystyrene, polymethyl methacrylate, polyimide, polyolefin, modified polyolefin, and a silicone resin.

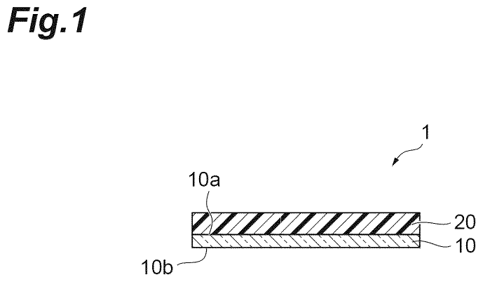

FIG. 1 is a schematic cross-sectional view illustrating an embodiment of a photosensitive element. A photosensitive element 1 of the present embodiment includes a support film 10 and a photosensitive layer 20 as illustrated in FIG. 1. The photosensitive layer 20 is provided on a first surface 10a of the support film 10. The support film 10 has a second surface 10b on a side opposite to the first surface 10a.

The support film of the present embodiment contains a lubricant from the viewpoint of improving slidability. The number of lubricants having a particle size of 1.0 μm or more contained in the first surface 10a of the support film may be 8 or less, 6 or less, 5 or less, 4 or less, or 3 or less, per 0.0225 mm², from the viewpoint of further reducing the number of defects of a resist. The number of lubricants of the present embodiment is an average value per unit area of 0.0225 mm² (0.150 mm×0.150 mm) of the first surface 10a of the support film. Note that, the lubricant having a particle size of 1.0 μm or more also includes an aggregate of a lubricant having a particle size of 1.0 μm or less.

The support film of the present embodiment may contain a lubricant having a particle size of less than 1.0 μm. The number of lubricants having a particle size of less than 1.0 μm contained in the first surface 10a may be 10 to 160, and may be 15 to 150, 20 to 140, or 25 to 130, per 0.0225 mm², from the viewpoint of further enhancing the slidability of the support film.

It is preferable that the support film of the present embodiment does not contain a lubricant having a particle size of more than 3.0 μm from the viewpoint of suppressing resist defects. Therefore, the upper limit value of the size of the lubricant (the maximum particle size of the lubricant) having a particle size of 1.0 μm or more contained in the first surface 10a may be 3.0 μm or less, 2.5 μm or less, 2.0 μm or less, 1.5 μm or less, or 1.3 μm or less.

The size and number of lubricants can be measured using a confocal microscope. As the confocal microscope, a hybrid laser microscope OPTELICS HYBRID (manufactured by Lasertec Corporation, trade name) and the like can be used. The observation with the confocal microscope is a measurement method in which reflected light from an object to be observed is detected by a light receiving portion. In a case where the object to be observed is brought to a focus (comes into focus), reflected light is strongly obtained, and an intensity of light is strongly observed (light is observed in white in many cases). In a case where the object to be observed is not brought to a focus (misses the point), an intensity of light is weakly observed (light is observed in black in many cases).

The numerical aperture (Na) of an objective lens used in observation may be 0.8 from the viewpoint of easily performing observation in an efficient manner with high accuracy. In a case where the numerical aperture is 0.8, as compared to a case where the numerical aperture is more than 0.8, since it is easy to suppress that the lens and the object to be observed are in contact with each other to cause contamination of the microscope and an excessive increase in magnification is suppressed, a decrease in detection level caused by a decrease in quantity of light of a field of view is easy to be suppressed. Furthermore, in a case where the numerical aperture (Na) is 0.8, as compared to a case where the numerical aperture is less than 0.8, since a decrease in resolution is suppressed so that the size detection of the object to be observed is less likely to be influenced by errors, measurement is easily performed with high accuracy.

In the observation with the confocal microscope, the measurement magnification may be 50 times, and the digital zooming in software may be 2 times. In a case where the measurement magnification is 50 times, as compared to a case where the measurement magnification is more than 50 times, a decrease in quantity of light of a field of view is suppressed so that a decrease in detection level is easy to be suppressed, and as compared to a case where the measurement magnification is less than 50 times, the sizes of defects are easy to be accurately measured. In a case where the digital zooming is 2 times, as compared to a case where the digital zooming is the actual size (without setting), a decrease in quantity of light of a field of view is suppressed so that a decrease in detection level is easy to be suppressed.

Examples of constituent materials for the support film include polyesters such as polyethylene terephthalate (PET), polybutylene terephthalate (PBT), and polyethylene-2,6-naphthalate (PEN); and polyolefins such as polypropylene and polyethylene. The support film may have a polyester film and may have a PET film from the viewpoint of easily suppressing occurrence of defects of a resist. The support film is a light transmissive film and may be a transparent resin film.

The support film may be single-layered and may be multi-layered. The support film may have a lubricant layer disposed on at least one surface of the inner layer portion (for example, a film of the above-described constituent material for the support film). For example, the support film may have a polyester film and a lubricant layer disposed on at least one surface of the polyester film. The lubricant layer can be formed using a known method such as a roll coater, a flow coater, a spray coater, a curtain flow coater, a dip coater, or a slit die coater. As the support film, it is preferable to use a biaxially oriented polyester film with a three-layer structure, and more preferable to use a biaxially oriented PET film with a three-layer structure.

A linear expansion coefficient (al) of the support film at 80 to 115° C. may be 30 to 170 ppm/° C., 40 to 150 ppm/° C., 45 to 125 ppm/° C., 60 to 125 ppm/° C., or 80 to 120 ppm/° C., from the viewpoint of the followability of the resist. A linear expansion coefficient (α2) of the support film at 115 to 130° C. may be 30 to 170 ppm/° C., 40 to 150 ppm/° C., 45 to 125 ppm/° C., 50 to 110 ppm/° C., or 55 to 100 ppm/° C., from the viewpoint of the followability of the resist. The linear expansion coefficient of the support film is a value obtained by measuring a TD (Transverse direction) direction of the support film at a tension mode by using a thermomechanical analyzer.

The haze value of the support film may be 0.01% or more, 0.05% or more, 0.1% or more, 0.3% or more, 0.5% or more, or 0.7% or more, from the viewpoint of easily improving handleability when the photosensitive element is laminated on the substrate, handleability when the photosensitive layer is formed on the support film, and the like. The haze value of the support film may be 3.0% or less, 1.5% or less, 0.8% or less, or 0.7% or less, from the viewpoint of easily obtaining favorable sensitivity and resolution. From these viewpoints, the haze value of the support film may be 0.01 to 3.0%, 0.01 to 1.5%, 0.01 to 0.8%, or 0.01 to 0.7%. The “haze value” means the degree of haze. The haze value of the support film can be measured using a commercially available haze meter (turbidimeter; for example, trade name “NDH-5000” manufactured by NIPPON DENSHOKU INDUSTRIES CO., LTD.) according to the method defined in JIS K 7105.

The light transmission (for example, light transmission in the whole range of wavelengths of 380 to 780 nm) of the support film may be in the following range. The light transmission of the support film may be 80% or more, 85% or more, 87% or more, 88% or more, or 89% or more. The light transmission of the support film may be 95% or less, 93% or less, 90% or less, or 89% or less. From these viewpoints, the light transmission of the support film may be 80 to 95%. The light transmission of the support film can be measured using a commercially available haze meter (for example, trade name “NDH-5000” manufactured by NIPPON DENSHOKU INDUSTRIES CO., LTD.).

The thickness of the support film or the thickness of the polyester film may be in the following range. The thickness may be 5 μm or more, 10 μm or more, 11 μm or more, 12 μm or more, 15 μm or more, or 16 μm or more, from the viewpoint that the support film is less likely to be torn when the support film is peeled off from the photosensitive element. The thickness may be 200 μm or less, 100 μm or less, 50 μm or less, 40 μm or less, 30 μm or less, 20 μm or less, or 18 μm or less, from the viewpoint of easily securing a focus latitude at the time of exposure. From these viewpoints, the thickness may be 5 to 200 μm, 11 to 100 μm, 12 to 50 μm, or 15 to 40 μm.

The photosensitive layer 20 is a layer formed from a photosensitive resin composition. The photosensitive resin composition used for forming the photosensitive layer 20 may contain (A) a binder polymer (a component (A)), (B) a photopolymerizable compound (a component (B)), and (C) a photopolymerization initiator (a component (C)).

Examples of constituent materials for the binder polymer that is the component (A) include an acrylic resin, a styrene resin, an epoxy resin, an amide resin, an amide-epoxy resin, an alkyd resin, and a phenolic resin. The component (A) may contain an acrylic resin from the viewpoint of easily obtaining favorable alkali developability. As the component (A), a binder polymer that is used in a conventional photosensitive resin composition can be used.

The component (A) can be produced, for example, by radical polymerization of a polymerizable monomer. Examples of the polymerizable monomer include styrene or a styrene derivative, acrylamides such as diacetone acrylamide, acrylonitriles, vinyl alcohol ethers such as vinyl-n-butyl ether, alkyl (meth)acrylate ester, benzyl (meth)acrylate ester, hydroxyalkyl (meth)acrylate, tetrahydrofurfuryl (meth)acrylate ester, dimethylaminoethyl (meth)acrylate ester, diethylaminoethyl (meth)acrylate ester, glycidyl (meth)acrylate ester, 2,2,2-trifluoroethyl (meth)acrylate, 2,2,3,3-tetrafluoropropyl (meth)acrylate, (meth)acrylic acid, α-bromoacrylic acid, α-chloracrylic acid, f-furyl (meth)acrylic acid, β-styryl (meth)acrylic acid, maleic acid, maleic anhydride, maleic acid monoesters such as monomethyl malate, monoethyl malate, and monoisopropyl malate, fumaric acid, cinnamic acid, α-cyanocinnamic acid, itaconic acid, crotonic acid, and propiolic acid. The polymerizable monomer can be used singly or in combination of two or more kinds thereof.

The component (A) may have a carboxy group from the viewpoint of alkali developability. The component (A) having a carboxy group can be produced, for example, by radical polymerization of a polymerizable monomer having a carboxy group with another polymerizable monomer. The polymerizable monomer having a carboxy group may be (meth)acrylic acid, or may be methacrylic acid.

From the viewpoint of improving alkali developability and alkali resistance in a well-balanced manner, the content of the structural unit based on the polymerizable monomer having a carboxy group may be 10 to 50% by mass, 15 to 40% by mass, 20 to 35% by mass, or 25 to 30% by mass, on the basis of the total amount of the component (A). When the content of the carboxy group is 10% by mass or more, there is a tendency that the alkali developability is improved, and when the content of the carboxy group is 50% by mass or less, there is a tendency that the alkali resistance is excellent.

From the viewpoint of adhesiveness and release property, the component (A) may have a structural unit based on styrene or a styrene derivative. The styrene derivative is a polymerizable compound in which the hydrogen atom at the α-position or of the aromatic ring of styrene such as vinyl toluene or α-methylstyrene has been substituted. The content of the structural unit based on the styrene or the styrene derivative in the component (A) may be 10 to 60% by mass, 15 to 55% by mass, 35 to 52% by mass, or 40 to 50% by mass. When the content thereof is 10% by mass or more, there is a tendency that adhesiveness is improved, and when the content thereof is 60% by mass or less, there are tendencies that an increase in size of the released pieces can be suppressed during the development, and thus an increase in time required for releasing can be suppressed.

The component (A) may have a structural unit based on benzyl (meth)acrylate ester from the viewpoint of improving resolution. The content of the structural unit derived from the benzyl (meth)acrylate ester in the component (A) may be 10 to 40% by mass, 15 to 35% by mass, 18 to 30% by mass, or 20 to 30% by mass.

The component (A) may have a structural unit based on alkyl (meth)acrylate ester from the viewpoint of improving plasticity. Examples of the alkyl (meth)acrylate ester include methyl (meth)acrylate ester, ethyl (meth)acrylate ester, propyl (meth)acrylate ester, butyl (meth)acrylate ester, pentyl (meth)acrylate ester, hexyl (meth)acrylate ester, heptyl (meth)acrylate ester, octyl (meth)acrylate ester, 2-ethylhexyl (meth)acrylate ester, nonyl (meth)acrylate ester, decyl (meth)acrylate ester, undecyl (meth)acrylate ester, and dodecyl (meth)acrylate ester.

The component (A) may have a structural unit based on hydroxyalkyl (meth)acrylate from the viewpoint of further improving resolution and adhesiveness. The hydroxyalkyl (meth)acrylate may be, for example, hydroxymethyl (meth)acrylate, hydroxyethyl (meth)acrylate, hydroxypropyl (meth)acrylate, hydroxybutyl (meth)acrylate, hydroxypentyl (meth)acrylate, hydroxyhexyl (meth)acrylate, and the like. Furthermore, in a case where the number of carbon atoms of the alkyl moiety in the hydroxyalkyl (meth)acrylate unit is 3 or more, the component (A) may have a branched structure.

The weight average molecular weight (Mw) of the component (A) may be 10000 or more, 15000 or more, 20000 or more, 25000 or more, or 30000 or more from the viewpoint that the adhesiveness of the resist pattern is excellent, and may be 100000 or less, 80000 or less, 70000 or less, 60000 or less, or 50000 or less from the viewpoint that development can be suitably performed. The degree of dispersion (Mw/Mn) of the component (A) may be, for example, 1.0 or more, 1.5 or more, or 1.8 or more, and may be 3.0 or less, 2.5 or less, or 2.0 or less from the viewpoint of further improving adhesiveness and resolution.

The weight average molecular weight (Mw) and the degree of dispersion (Mw/Mn) in the present specification can be obtained by measurement by gel permeation chromatography (GPC) and conversion using a calibration curve of standard polystyrene.

The acid value (solid-content acid value) of the component (A) may be 60 mgKOH/g or more, 80 mgKOH/g or more, 90 mgKOH/g or more, 100 mgKOH/g or more, 120 mgKOH/g or more, 140 mgKOH/g or more, or 160 mgKOH/g or more from the viewpoint that development can be suitably performed, and may be 250 mgKOH/g or less, 230 mgKOH/g or less, 210 mgKOH/g or less, 200 mgKOH/g or less, or 190 mgKOH/g or less from the viewpoint of improving the adhesiveness (developing solution resistance) of the resist pattern. The acid value of the component (A) can be adjusted by the content of the structural unit constituting the component (A) (for example, a structural unit derived from a (meth)acrylic acid).

The component (A) can be used singly or in combination of two or more kinds thereof. Examples of the component (A) in the case of being used in combination of two or more kinds thereof include two or more kinds of binder polymers each including a different polymerizable monomer, two or more kinds of binder polymers each having a different Mw, and two or more kinds of binder polymers each having a different degree of dispersion.

The content of the component (A) may be 30 to 80 parts by mass, 40 to 75 parts by mass, 50 to 70 parts by mass, or 50 to 60 parts by mass, with respect to 100 parts by mass of the total amount of the component (A) and a component (B) described below. When the content of the component (A) is within this range, the strength of the photo-cured area of the photosensitive layer becomes more favorable.

As the photopolymerizable compound that is the component (B), a compound having at least one ethylenically unsaturated bond in the molecule can be used. The component (B) can be used singly or in combination of two or more kinds thereof.

The ethylenically unsaturated bond of the component (B) is not particularly limited as long as photopolymerization is possible. Examples of the ethylenically unsaturated bond include α,β-unsaturated carbonyl groups such as a (meth)acryloyl group. Examples of the photopolymerizable compound having an α,β-unsaturated carbonyl group include α,β-unsaturated carboxylic acid esters of polyhydric alcohols, bisphenol-type (meth)acrylates, α,β-unsaturated carboxylic acid adducts of glycidyl group-containing compounds, (meth)acrylates having a urethane bond, nonylphenoxypolyethylene oxyacrylate, (meth)acrylates having a phthalic acid skeleton, and alkyl (meth)acrylate esters.

Examples of the α,β-unsaturated carboxylic acid esters of polyhydric alcohols include polyethylene glycol di(meth)acrylate in which the number of ethylene groups is 2 to 14, polypropylene glycol di(meth)acrylate in which the number of propylene groups is 2 to 14, polyethylene-polypropylene glycol di(meth)acrylate in which the number of ethylene groups is 2 to 14 and the number of propylene groups is 2 to 14, trimethylol propane di(meth)acrylate, trimethylol propane tri(meth)acrylate, EO-modified trimethylol propane tri(meth)acrylate, PO-modified trimethylol propane tri(meth)acrylate, EO,PO-modified trimethylol propane tri(meth)acrylate, tetramethylolmethane tri(meth)acrylate, tetramethylolmethane tetra(meth)acrylate, and a (meth)acrylate compound having a skeleton derived from dipentaerythritol or pentaerythritol. The term “EO-modified” means having a block structure of an ethylene oxide (EO) group, and the term “PO-modified” means having a block structure of a propylene oxide (PO) group.

From the viewpoint of improving the flexibility of the resist pattern, the component (B) may contain polyalkylene glycol di(meth)acrylate. The polyalkylene glycol di(meth)acrylate may have at least one of the EO group and the PO group, and may have both the EO group and the PO group. In the polyalkylene glycol di(meth)acrylate having both the EO group and the PO group, the EO group and the PO group may be present as continuous blocks or present randomly. Furthermore, the PO group may be either an oxy-n-propylene group or an oxyisopropylene group. Note that, in a (poly)oxyisopropylene group, the secondary carbon of the propylene group may be bonded to an oxygen atom, and the primary carbon may be bonded to an oxygen atom.

Examples of commercially available products of polyalkylene glycol di(meth)acrylate include FA-023M (manufactured by Showa Denko Materials Co., Ltd.), FA-024M (manufactured by Showa Denko Materials Co., Ltd.), and NK ESTETR HEMA-9P (manufactured by SHIN-NAKAMURA CHEMICAL Co., Ltd.).

From the viewpoint of improving the flexibility of the resist pattern, the component (B) may contain a (meth)acrylate having a urethane bond. Examples of the (meth)acrylate having a urethane bond include addition reaction products of (meth)acrylic monomers with an OH group at the β-position and diisocyanate (such as isophorone diisocyanate, 2,6-toluene diisocyanate, 2,4-toluene diisocyanate, or 1,6-hexamethylene diisocyanate), tris((meth)acryloxytetraethylene glycol isocyanate) hexamethylene isocyanurate, EO-modified urethane di(meth)acrylate, and EO, PO-modified urethane di(meth)acrylate.

Examples of commercially available products of the EO-modified urethane di(meth)acrylate include “UA-11” and “UA-21EB” (manufactured by SHIN-NAKAMURA CHEMICAL Co., Ltd.). Examples of commercially available products of the EO, PO-modified urethane di(meth)acrylate include “UA-13” (manufactured by SHIN-NAKAMURA CHEMICAL Co., Ltd.).

From the viewpoint of easily forming a thick resist pattern and improving resolution and adhesiveness in a well-balanced manner, the component (B) may contain a (meth)acrylate compound having a skeleton derived from dipentaerythritol or pentaerythritol. The (meth)acrylate compound having a skeleton derived from dipentaerythritol or pentaerythritol preferably has four or more (meth)acryloyl groups and may be dipentaerythritol penta(meth)acrylate or dipentaerythritol hexa(meth)acrylate.

As the component (B), a polyfunctional (meth)acrylate compound obtained by reacting an α,β-unsaturated carboxylic acid with a polyhydric alcohol may be contained. The polyfunctional (meth)acrylate compound may have at least one of the EO group and the PO group, and may have both the EO group and the PO group. As such a compound, dipentaerythritol (meth)acrylate having an EO group, and the like can be used. Examples of commercially available products of the dipentaerythritol (meth)acrylate having an EO group include DPEA-12 (manufactured by Nippon Kayaku Co., Ltd.).

From the viewpoint of improving resolution and release property after curing, the component (B) may contain bisphenol-type (meth)acrylates, and may contain a bisphenol A-type (meth)acrylate among the bisphenol-type (meth)acrylates. Examples of the bisphenol A-type (meth)acrylate include 2,2-bis(4-((meth)acryloxypolyethoxy)phenyl)propane, 2,2-bis(4-((meth)acryloxypolypropoxy)phenyl)propane, 2,2-bis(4-((meth)acryloxypolybutoxy)phenyl)propane, and 2,2-bis(4-((meth)acryloxypolyethoxypolypropoxy)phenyl)propane.

Examples of commercially available products of 2,2-bis(4-((meth)acryloxydiethoxy)phenyl)propane include BPE-200 (manufactured by SHIN-NAKAMURA CHEMICAL Co., Ltd.), and examples of commercially available products of 2,2-bis(4-(methacryloxypentaethoxy)phenyl)propane include BPE-500 (manufactured by SHIN-NAKAMURA CHEMICAL Co., Ltd.) and FA-321M (manufactured by Showa Denko Materials Co., Ltd.).

Examples of the nonylphenoxypolyethylene oxyacrylate include nonylphenoxytetraethylene oxyacrylate, nonylphenoxypentaethylene oxyacrylate, nonylphenoxyhexaethylene oxyacrylate, nonylphenoxyheptaethylene oxyacrylate, nonylphenoxyoctaethylene oxyacrylate, nonylphenoxynonaethylene oxyacrylate, nonylphenoxydecaethylene oxyacrylate, and nonylphenoxyundecaethylene oxyacrylate.

Examples of the (meth)acrylates having a phthalic acid skeleton include γ-chloro-β-hydroxypropyl-β′-(meth)acryloyloxyethyl-o-phthalate, β-hydroxyethyl-β′-(meth)acryloyloxyethyl-o-phthalate, and β-hydroxypropyl-β′-(meth)acryloyloxyethyl-o-phthalate. The γ-chloro-β-hydroxypropyl-β′-methacryloyloxyethyl-o-phthalate is commercially available as FA-MECH (manufactured by Showa Denko Materials Co., Ltd.).

The photopolymerization initiator that is the component (C) is not particularly limited as long as it can polymerize the component (B), and can be appropriately selected from photopolymerization initiators generally used. The component (C) can be used singly or in combination of two or more kinds thereof.

Examples of the component (C) include an imidazole compound, an aromatic ketone (excluding a compound corresponding to the benzophenone compound), a quinone compound, a benzoin compound, an acridine compound, an N-phenylglycine compound, and a benzyl derivative.

Examples of the imidazole compound include 2-(o-chlorophenyl)-4,5-diphenylbiimidazole, 2,2′,5-tris-(o-chlorophenyl)-4-(3,4-dimethoxyphenyl)-4′,5′-diphenylbiimidazole, 2,4-bis-(o-chlorophenyl)-5-(3,4-dimethoxyphenyl)-diphenylbiimidazole, 2,4,5-tris-(o-chlorophenyl)-diphenylbiimidazole, 2-(o-chlorophenyl)-bis-4,5-(3,4-dimethoxyphenyl)-biimidazole, 2,2′-bis-(2-fluorophenyl)-4,4′,5,5′-tetrakis-(3-methoxyphenyl)-biimidazole, 2,2′-bis-(2,3-difluoromethylphenyl)-4,4′,5,5′-tetrakis-(3-methoxyphenyl)-biimidazole, 2,2′-bis-(2,4-difluorophenyl)-4,4′,5,5′-tetrakis-(3-methoxyphenyl)-biimidazole, and 2,2′-bis-(2,5-difluorophenyl)-4,4′,5,5′-tetrakis-(3-methoxyphenyl)-biimidazole.

Examples of the acridine compound include 9-phenylacridine, 9-(p-methylphenyl)acridine, 9-(m-methylphenyl)acridine, 9-(p-chlorophenyl)acridine, 9-(m-chlorophenyl)acridine, 9-aminoacridine, 9-dimethylaminoacridine, 9-diethylaminoacridine, 9-pentylaminoacridine, bis(9-acridinyl)alkanes such as 1,2-bis(9-acridinyl)ethane, 1,4-bis(9-acridinyl)butane, 1,6-bis(9-acridinyl)hexane, 1,8-bis(9-acridinyl)octane, 1,10-bis(9-acridinyl)decane, 1,12-bis(9-acridinyl)dodecane, 1,14-bis(9-acridinyl)tetradecane, 1,16-bis(9-acridinyl)hexadecane, 1,18-bis(9-acridinyl)octadecane, and 1,20-bis(9-acridinyl)eicosane, 1,3-bis(9-acridinyl)-2-oxapropane, 1,3-bis(9-acridinyl)-2-thiapropane, and 1,5-bis(9-acridinyl)-3-thiapentane.

Examples of the N-phenylglycine compound include N-phenylglycine, N-methyl-N-phenylglycine, and N-ethyl-N-phenylglycine. Examples of the aromatic ketone include 2-benzyl-2-dimethylamino-1-(4-morpholinophenyl)-butanone-1 and 2-methyl-1-[4-(methylthio)phenyl]-2-morpholino-propanone-1. Examples of the quinone compound include alkylanthraquinone. Examples of the benzoin compound include benzoin, alkyl benzoin, and a benzoin ether compound (such as benzoin alkyl ether). Examples of the benzyl derivative include benzyl dimethylketol.

The content of the component (C) may be 0.1 to 10 parts by mass, 1 to 5 parts by mass, or 2 to 4.5 parts by mass, with respect to 100 parts by mass of the total amount of the component (A) and the component (B). When the content of the component (C) is 0.1 parts by mass or more, there is a tendency that photosensitivity, resolution, and adhesiveness are improved, and when the content of the component (C) is 10 parts by mass or less, there is a tendency that the resist pattern formability is more excellent.

The photosensitive resin composition of the present embodiment may further contain a photosensitizer as a component (D). By containing the component (D), the absorption wavelength of active light rays used for exposure can be effectively utilized. The component (D) can be used singly or in combination of two or more kinds thereof.

Examples of the component (D) include a pyrazoline compound, a benzophenone compound, an anthracene compound, a coumarin compound, a xanthone compound, a thioxanthone compound, an oxazole compound, a benzoxazole compound, a thiazole compound, a benzothiazole compound, a triazole compound, a stilbene compound, a triazine compound, a thiophene compound, a naphthalimide compound, a triarylamine compound, and an aminoacridine compound. The sensitizer may contain at least one selected from the group consisting of a pyrazoline compound, a benzophenone compound, an anthracene compound, and a coumarin compound, from the viewpoint of easily suppressing occurrence of defects of a resist, the viewpoint of easily shortening the minimum developing time, and the viewpoint of easily obtaining favorable sensitivity, resolution, and adhesiveness.

Examples of the pyrazoline compound include 1-(4-methoxyphenyl)-3-styryl-5-phenyl-pyrazoline, 1-phenyl-3-(4-methoxystyryl)-5-(4-methoxyphenyl)-pyrazoline, 1,5-bis-(4-methoxyphenyl)-3-(4-methoxystyryl)-pyrazoline, 1-(4-isopropylphenyl)-3-styryl-5-phenyl-pyrazoline, 1-phenyl-3-(4-isopropylstyryl)-5-(4-isopropylphenyl)-pyrazoline, 1,5-bis-(4-isopropylphenyl)-3-(4-isopropylstyryl)-pyrazoline, 1-(4-methoxyphenyl)-3-(4-tert-butyl-styryl)-5-(4-tert-butyl-phenyl)-pyrazoline, 1-(4-tert-butyl-phenyl)-3-(4-methoxystyryl)-5-(4-methoxyphenyl)-pyrazoline, 1-(4-isopropyl-phenyl)-3-(4-tert-butyl-styryl)-5-(4-tert-butyl-phenyl)-pyrazoline, 1-(4-tert-butyl-phenyl)-3-(4-isopropyl-styryl)-5-(4-isopropyl-phenyl)-pyrazoline, 1-(4-methoxyphenyl)-3-(4-isopropylstyryl)-5-(4-isopropylphenyl)-pyrazoline, 1-(4-isopropyl-phenyl)-3-(4-methoxystyryl)-5-(4-methoxyphenyl)-pyrazoline, 1-phenyl-3-(3,5-dimethoxystyryl)-5-(3,5-dimethoxyphenyl)-pyrazoline, 1-phenyl-3-(3,4-dimethoxystyryl)-5-(3,4-dimethoxyphenyl)-pyrazoline, 1-phenyl-3-(2,6-dimethoxystyryl)-5-(2,6-dimethoxyphenyl)-pyrazoline, 1-phenyl-3-(2,5-dimethoxystyryl)-5-(2,5-dimethoxyphenyl)-pyrazoline, 1-phenyl-3-(2,3-dimethoxystyryl)-5-(2,3-dimethoxyphenyl)-pyrazoline, 1-phenyl-3-(2,4-dimethoxystyryl)-5-(2,4-dimethoxyphenyl)-pyrazoline, 1-(4-methoxyphenyl)-3-(3,5-dimethoxystyryl)-5-(3,5-dimethoxyphenyl)-pyrazoline, 1-(4-methoxyphenyl)-3-(3,4-dimethoxystyryl)-5-(3,4-dimethoxyphenyl)-pyrazoline, 1-(4-methoxyphenyl)-3-(2,6-dimethoxystyryl)-5-(2,6-dimethoxyphenyl)-pyrazoline, 1-(4-methoxyphenyl)-3-(2,5-dimethoxystyryl)-5-(2,5-dimethoxyphenyl)-pyrazoline, 1-(4-methoxyphenyl)-3-(2,3-dimethoxystyryl)-5-(2,3-dimethoxyphenyl)-pyrazoline, 1-(4-methoxyphenyl)-3-(2,4-dimethoxystyryl)-5-(2,4-dimethoxyphenyl)-pyrazoline, 1-(4-tert-butyl-phenyl)-3-(3,5-dimethoxystyryl)-5-(3,5-dimethoxyphenyl)-pyrazoline, 1-(4-tert-butyl-phenyl)-3-(3,4-dimethoxystyryl)-5-(3,4-dimethoxyphenyl)-pyrazoline, 1-(4-tert-butyl-phenyl)-3-(2,6-dimethoxystyryl)-5-(2,6-dimethoxyphenyl)-pyrazoline, 1-(4-tert-butyl-phenyl)-3-(2,5-dimethoxystyryl)-5-(2,5-dimethoxyphenyl)-pyrazoline, 1-(4-tert-butyl-phenyl)-3-(2,3-dimethoxystyryl)-5-(2,3-dimethoxyphenyl)-pyrazoline, 1-(4-tert-butyl-phenyl)-3-(2,4-dimethoxystyryl)-5-(2,4-dimethoxyphenyl)-pyrazoline, 1-(4-isopropyl-phenyl)-3-(3,5-dimethoxystyryl)-5-(3,5-dimethoxyphenyl)-pyrazoline, 1-(4-isopropyl-phenyl)-3-(3,4-dimethoxystyryl)-5-(3,4-dimethoxyphenyl)-pyrazoline, 1-(4-isopropyl-phenyl)-3-(2,6-dimethoxystyryl)-5-(2,6-dimethoxyphenyl)-pyrazoline, 1-(4-isopropyl-phenyl)-3-(2,5-dimethoxystyryl)-5-(2,5-dimethoxyphenyl)-pyrazoline, 1-(4-isopropyl-phenyl)-3-(2,3-dimethoxystyryl)-5-(2,3-dimethoxyphenyl)-pyrazoline, and 1-(4-isopropyl-phenyl)-3-(2,4-dimethoxystyryl)-5-(2,4-dimethoxyphenyl)-pyrazoline. The sensitizer may contain 1-phenyl-3-(4-methoxystyryl)-5-(4-methoxyphenyl)-pyrazoline from the viewpoint of easily obtaining favorable resolution and adhesiveness.

Examples of the benzophenone compound include benzophenone; N,N,N′,N′-tetraalkyl-4,4′-diaminobenzophenone such as N,N,N′,N′-tetramethyl-4,4′-diaminobenzophenone (also known as: Michler's ketone) and N,N,N′,N′-tetraethyl-4,4′-diaminobenzophenone; and dialkylaminobenzophenone such as 4-methoxy-4′-dimethylaminobenzophenone. The sensitizer may contain N,N,N′,N′-tetraalkyl-4,4′-diaminobenzophenone from the viewpoint of easily obtaining favorable resolution and adhesiveness.

Examples of the anthracene compound include 9,10-dimethoxyanthracene, 9,10-diethoxyanthracene, 9,10-dipropoxyanthracene, 9,10-dibutoxyanthracene, and 9,10-dipentoxyanthracene. The sensitizer may contain 9,10-dialkoxyanthracene from the viewpoint of easily obtaining favorable sensitivity.

Examples of the coumarin compound include 7-amino-4-methylcoumarin, 7-dimethylamino-4-methylcoumarin, 7-diethylamino-4-methylcoumarin, 7-methylamino-4-methylcoumarin, 7-ethylamino-4-methylcoumarin, 7-aminocyclopenta[c]coumarin, 7-dimethylaminocyclopenta[c]coumarin, 7-diethylaminocyclopenta[c]coumarin, 4,6-dimethyl-7-dimethylaminocoumarin, 4,6-dimethyl-7-ethylaminocoumarin, 4,6-dimethyl-7-diethylaminocoumarin, 4,6-diethyl-7-dimethylaminocoumarin, 4,6-diethyl-7-ethylaminocoumarin, 4,6-diethyl-7-dimethylaminocoumarin, 3-benzoyl-7-diethylaminocoumarin, 3,3′-carbonylbis(7-diethylaminocoumarin), and 2,3,6,7-tetrahydro-9-methyl-1H,5H,11H-[1]benzopyrano [6,7,8-ii]quinolizin-11-one. The sensitizer may contain 2,3,6,7-tetrahydro-9-methyl-1H,5H,11H-[1]benzopyrano[6,7,8-ii]quinolizin-11-one from the viewpoint of easily obtaining favorable sensitivity.

From the viewpoint of improving photosensitivity and resolution, the content of the component (D) may be 0.01 to 5 parts by mass, 0.01 to 1 parts by mass, or 0.01 to 0.2 parts by mass, with respect to 100 parts by mass of the total amount of the component (A) and the component (B).

The photosensitive resin composition of the present embodiment may further contain, as necessary, additives such as a dye, a photochromic agent, a thermal development inhibitor, a plasticizer, a pigment, a filler, an antifoaming agent, a flame retardant, a tackifier, a leveling agent, a release promoter, an antioxidant, an aroma, an imaging agent, a thermal crosslinking agent, and a polymerization inhibitor. These additives can be used singly or in combination of two or more kinds thereof.

Examples of the dye include Malachite Green, Victoria Pure Blue, Brilliant Green, and Methyl Violet. Examples of the photochromic agent include tribromophenylsulfone, leuco crystal violet, diphenylamine, benzylamine, triphenylamine, diethylaniline, and o-chloroaniline. Examples of the plasticizer include p-toluenesulfonamide.

The photosensitive resin composition can be prepared as a solution having a solid content of about 30 to 60% by mass, as necessary, by dissolving the photosensitive resin composition in a solvent such as methanol, ethanol, acetone, methyl ethyl ketone, methyl cellosolve, ethyl cellosolve, toluene, N,N-dimethylformamide, or propylene glycol monomethyl ether, or a mixed solvent of such solvents.

The thickness of the photosensitive layer 20 may be 1 to 200 μm, 5 to 100 μm, 10 to 50 μm, or 10 to 30 μm.

The photosensitive element of the present embodiment may include a protective film (not illustrated) on a side of the photosensitive layer 20 opposite to the support film 10. As the protective film, it is preferable to use a film such that the adhesive force between the photosensitive layer 20 and the support film 10 is smaller than the adhesive force between the photosensitive layer 20 and the protective film. As the protective film, polyolefin films such as polyethylene and polypropylene can be used. The protective film may be a polyethylene film.

The thickness of the protective film may be 5 to 100 μm, 5 to 70 μm, 10 to 60 μm, 10 to 50 μm, 15 to 40 μm, or 15 to 30 μm.

The photosensitive element of the present embodiment may include an intermediate layer (not illustrated) between the support film and the photosensitive layer. The adhesive force between the support film and the intermediate layer may be smaller than the adhesive force between the intermediate layer and the photosensitive layer. The intermediate layer may have water solubility, and may have dissolubility with respect to a developing solution. The intermediate layer is a layer formed using a resin composition for forming an intermediate layer described below.

The resin composition for forming an intermediate layer may contain a water-soluble resin. By containing a water-soluble resin, there is a tendency that the dissolubility of an intermediate layer to be formed is improved. Furthermore, since it becomes easy to maintain the layer isolation between the intermediate layer to be formed and the photosensitive layer for a long period of time, there is a tendency that stability is improved. Examples of the water-soluble resin include polyvinyl alcohol and polyvinylpyrrolidone. From the viewpoint that an oxygen transmission coefficient is low and deactivation of radicals occurring due to active light rays used for exposure can be further suppressed, the resin composition for forming an intermediate layer may contain polyvinyl alcohol. The polyvinyl alcohol can be obtained, for example, by saponification of polyvinyl acetate obtained by polymerization of vinyl acetate. The saponification degree of the polyvinyl alcohol used in the present embodiment may be 50 mol % or more, 70 mol % or more, or 80 mol % or more. By using polyvinyl alcohol having a saponification degree of 50 mol % or more, there are tendencies that the gas barrier properties of the intermediate layer can be further improved, and the resolution of a resist pattern to be formed can be further improved. Note that, the “saponification degree” in the present specification refers to a value measured according to JIS K 6726 (1994) (Testing methods for polyvinyl alcohol) defined in Japanese Industrial Standards. Furthermore, the upper limit value of such a saponification degree may be 100 mol %.

The average polymerization degree of polyvinyl alcohol may be 300 to 3500, 300 to 2500, or 300 to 1000. Furthermore, the average polymerization degree of polyvinylpyrrolidone may be 10000 to 100000 or 10000 to 50000. As for the above-described polyvinyl alcohol, two or more kinds of polyvinyl alcohols having different saponification degrees, different viscosities, different polymerization degrees, different modification types, and the like may be used in combination.

The resin composition for forming an intermediate layer may contain a resin having dissolubility with respect to a developing solution. As the resin having dissolubility with respect to a developing solution, for example, the component (A) used in the photosensitive resin composition may be contained, and the component (B) may be contained. By containing the resin having dissolubility with respect to a developing solution, there are tendencies that the adhesiveness between the intermediate layer to be formed and the photosensitive layer is improved and the photosensitive layer is easily formed on the intermediate layer to be formed.

In order to improve the handleability of the resin composition or adjust the viscosity and storage stability, the resin composition for forming an intermediate layer can contain at least one kind of solvents as necessary. Examples of the solvent include water and an organic solvent. Examples of the organic solvent include methanol, acetone, toluene, and a mixed solvent of these. From the viewpoint of improving drying efficiency at the time of forming the intermediate layer, methanol may be contained. Furthermore, in a case where the resin composition for forming an intermediate layer contains a water-soluble resin, water, and methanol, the content of the methanol may be 1 to 100 parts by mass, 10 to 80 parts by mass, or 20 to 60 parts by mass, with respect to 100 parts by mass of water, from the viewpoint of dissolubility with respect to the water-soluble resin. The content of the water-soluble resin may be 1 to 50 parts by mass, 5 to 40 parts by mass, or 10 to 30 parts by mass, with respect to 100 parts by mass of water.

The resin composition for forming an intermediate layer may be blended with known additives such as a surfactant, a plasticizer, and a leveling agent. Examples of the leveling agent include a silicone-based leveling agent. Examples of commercially available products of the silicone-based leveling agent include POLYFLOW KL-401 (manufactured by Kyoeisha Chemical Co., Ltd.). In the case of containing a leveling agent, the content of the leveling agent may be 0.01 to 2.0 parts by mass, 0.03 to 1.5 parts by mass, or 0.05 to 1.0 parts by mass, with respect to 100 parts by mass of the resin composition for forming an intermediate layer, from the viewpoint of ease of formation of an intermediate layer.

From the viewpoint of improving releasability with the support film, a silicone-based surfactant or a fluorine-based surfactant can be contained as the surfactant. These surfactants can be used singly or in combination of two or more kinds thereof. In the case of containing a surfactant, the content of the surfactant may be 0.01 to 1.0 parts by mass, 0.05 to 0.5 parts by mass, or 0.1 to 0.3 parts by mass, with respect to 100 parts by mass of the resin composition for forming an intermediate layer, from the viewpoint of ease of formation of an intermediate layer.

For example, from the viewpoint of improving ease of formation of an intermediate layer, a polyhydric alcohol compound can be contained as the plasticizer. Examples of the plasticizer include glycerins such as glycerin, diglycerin, and triglycerin; (poly)alkylene glycols such as ethylene glycol, diethylene glycol, triethylene glycol, tetraethylene glycol, polyethylene glycol, propylene glycol, dipropylene glycol, and polypropylene glycol; and trimethylol propane. These plasticizers can be used singly or in combination of two or more kinds thereof.

The thickness of the intermediate layer is not particularly limited, and may be 12 μm or less, 10 μm or less, or 8 μm or less, from the viewpoint of developability. Furthermore, the thickness of the intermediate layer may be 1.0 μm or more, 1.5 μm or more, or 2.0 μm or more, from the viewpoint of ease of formation of the intermediate layer and resolution.

### [Method for Forming Resist Pattern]

A method for forming a resist pattern of the present embodiment includes a lamination step of laminating the photosensitive layer 20 of the photosensitive element 1 on a substrate in order of the photosensitive layer and the support film, an exposure step of irradiating a predetermined part of the photosensitive layer 20 with an active light ray through the support film 10 to form a photo-cured area, and a development step of removing an area other than the photo-cured area in the photosensitive layer 20.

In the lamination step, for example, the photosensitive layer and the support film of the photosensitive element are laminated on the substrate in this order. In the lamination step, as a method of laminating the photosensitive layer 20 on the substrate, for example, in a case where the protective film exists on the photosensitive layer 20, a method of laminating the photosensitive layer on the substrate by pressure-bonding the substrate at a pressure of about 0.1 to 1 MPa while heating the photosensitive layer 20 to about 70 to 130° C. after removing the protective film is exemplified. In the lamination step, lamination can also be performed under reduced pressure. Note that, a surface of the substrate on which the photosensitive layer 20 is laminated is usually a metal surface, but is not particularly limited. Furthermore, in order to further improve laminating properties, the substrate may be subjected to a preheating treatment.

Next, in the exposure step, for example, a predetermined part of the photosensitive layer 20 is irradiated with an active light ray through the support film 10 to form a photo-cured area on the photosensitive layer 20. Examples of the exposure method include a method of emitting active light rays imagewise through a negative or positive mask pattern, referred to as artwork (mask exposure method), a method of emitting active light rays imagewise by a projection exposure method, and a method of emitting active light rays imagewise by a direct writing exposure method such as an LDI (Laser Direct Imaging) exposure method or a DLP (Digital Light Processing) exposure method.

Known light sources can be used as a light source for the active light ray, and for example, a carbon arc lamp, a mercury vapor arc lamp, a high-pressure mercury lamp, a xenon lamp, a gas laser such as an argon laser, a solid-state laser such as a YAG laser, and a semiconductor laser, which efficiently emit ultraviolet rays or visible light, are used.

From the viewpoint of improving adhesiveness, post exposure bake (PEB) may be performed after the exposure and before the development. The temperature in the case of performing PEB may be 50 to 100° C. As a heating machine, a hot plate, a box-type dryer, a heating roll, and the like may be used.

In the development step, at least a part of the photosensitive layer other than the photo-cured area is removed from the substrate, so that a resist pattern is formed on the substrate.

In the development step, after the support film 10 is released and removed from the photosensitive layer 20, an area other than the photo-cured area in the photosensitive layer is removed. In the development step, a resist pattern can be produced, for example, by removing and developing an unexposed area (non-photo-cured area) of the photosensitive layer 20 with wet development using a developing solution such as an alkaline aqueous solution, an aqueous developing solution, or an organic solvent, dry development, or the like.

Examples of the alkaline aqueous solution include a 0.1 to 5% by mass sodium carbonate solution, a 0.1 to 5% by mass potassium carbonate solution, and a 0.1 to 5% by mass sodium hydroxide solution. The pH of the alkaline aqueous solution is preferably in a range of 9 to 11. The temperature of the alkaline aqueous solution is adjusted according to the developability of the photosensitive layer 20. Furthermore, the alkaline aqueous solution may contain a surfactant, an antifoaming agent, an organic solvent, and the like. Examples of the development method include a dip method, a spray method, brushing, and scrubbing.

As a treatment after the development step, heating at about 60 to 250° C. or exposure at about 0.2 to 10 J/cm² may be performed as necessary to further cure the resist pattern.

### [Method for Producing Printed Wiring Board]

A method for producing a printed wiring board of the present embodiment includes a step of subjecting a substrate having a resist pattern formed by the above-described method for forming a resist pattern to an etching treatment or a plating treatment to form a conductor pattern. Herein, the etching or plating of the substrate can be performed by etching or plating the surface of the substrate by a known method using the resist pattern as a mask.

Examples of an etching solution used in etching include a cupric chloride solution, a ferric chloride solution, and an alkali etching solution. Examples of the plating include copper plating, solder plating, nickel plating, and gold plating.

After etching or plating is performed, the resist pattern can be released, for example, with an aqueous solution of stronger alkalinity than the alkaline aqueous solution used for the development. As this strong alkaline aqueous solution, for example, a 1 to 10% by mass sodium hydroxide aqueous solution and a 1 to 10% by mass potassium hydroxide aqueous solution are used. Furthermore, examples of the releasing method include a dip method and a spray method. Note that, a printed wiring board on which the resist pattern has been formed may be a multilayer printed wiring board, and may have small through-holes.

In the case of subjecting a substrate including an insulation layer and a conductor layer formed on the insulation layer to plating, it is necessary to remove an area of the conductor layer other than the resist pattern. Examples of this removing method include a method of releasing the resist pattern and then lightly etching; and a method of performing solder plating or the like after the plating and then releasing the resist pattern to leave a solder mask on the wiring sections, and then performing treatment using an etching solution capable of etching only the conductor layer on the sections where the solder mask is not formed.

### EXAMPLES

Hereinafter, the contents of the present disclosure will be described in more detail with reference to Examples and Comparative Example; however, the present invention is not limited to Examples.

### [Photosensitive Resin Composition]

Respective components were mixed at blending amounts (parts by mass) shown in Table 1 to prepare a photosensitive resin composition. The details of respective components shown in Table 1 are as follows.

### (Binder Polymer)

A-1: Ethylene glycol monomethyl ether/toluene solution (solid content: 49% by mass) of copolymer of methacrylic acid/methyl methacrylate/styrene/benzyl methacrylate (mass ratio: 27/5/45/23, Mw: 45000, acid value: 180 mgKOH/g)
A-2: Ethylene glycol monomethyl ether/toluene solution (solid content: 49% by mass) of copolymer of methacrylic acid/styrene/benzyl methacrylate/2-hydroxyethyl methacrylate (mass ratio: 27/50/20/3, Mw: 35000, acid value: 176 mgKOH/g)

The Mw of the binder polymer was calculated by measurement by gel permeation chromatography (GPC)under the following conditions and conversion using a calibration curve of standard polystyrene. Pump: L-2130 type (manufactured by Hitachi High-Tech Co., Ltd.) Detector: L-2490 type RI (manufactured by Hitachi High-Tech Co., Ltd.) Column oven: L-2350 (manufactured by Hitachi High-Tech Co., Ltd.) Column: Gelpack GL-R440+Gelpack GL-R450+Gelpack GL-R400M (three in total) (manufactured by Showa Denko Materials Co., Ltd.)
Column size: 10.7 mm I.D×300 mm
Eluent: Tetrahydrofuran
Sample concentration: 10 mg/2 mL
Injection amount: 200 μL
Flow rate: 2.05 mL/min
Measurement temperature: 25° C.

The acid value of the binder polymer was measured by the following procedure. First, the binder polymer was weighed in an Erlenmeyer flask. Next, the binder polymer was dissolved by addition of a mixed solvent (mass ratio: toluene/methanol=70/30), and then a phenolphthalein solution was added as an indicator thereto. Then, the acid value was obtained by performing a titration using a 0.1 mol/L (N/10) potassium hydroxide solution (alcohol solution).

### (Photopolymerizable Compound)

FA-321M: EO-modified bisphenol A dimethacrylate (manufactured by Showa Denko Materials Co., Ltd., the number of EO groups: 10 (average value))
FA-024M: Polyalkylene glycol dimethacrylate (manufactured by Showa Denko Materials Co., Ltd., the number of EO groups: 12 (average value), the number of PO groups: 4 (average value))
BPE-200: 2,2-Bis(4-(methacryloxydiethoxy)phenyl)propane (manufactured by SHIN-NAKAMURA CHEMICAL Co., Ltd.)
BP-2EM: 2,2-Bis(4-(methacryloxydiethoxy)phenyl)propane (manufactured by Kyoeisha Chemical Co., Ltd.)

### (Photopolymerization Initiator)

B-CIM: 2,2′-Bis(2-chlorophenyl)-4,4′,5,5′-tetraphenyl biimidazole (manufactured by Hodogaya Chemical Co., Ltd.)

### (Sensitizer)

EAB: 4,4′-Bis(diethylamino)benzophenone (manufactured by Hodogaya Chemical Co., Ltd.)
PZ-501D: 1-Phenyl-3-(4-methoxystyryl)-5-(4-methoxyphenyl)-pyrazoline (manufactured by NIPPON CHEMICAL WORKS CO., LTD.)
Coumarin 102: 2,3,6,7-tetrahydro-9-methyl-1H,5H,11H-[1]benzopyrano[6,7,8-ij]quinolizin-11-one (manufactured by Tokyo Chemical Industry Co., Ltd.)

### (Polymerization Inhibitor)

TBC: 4-tert-Butylcatechol (manufactured by DIC Corporation) LA-7RD: 4-Hydroxy-2,2,6,6-tetramethylpiperidine-N-oxyl (manufactured by ADEKA CORPORATION) (Dye)
MKG: Malachite green (manufactured by OSAKA ORGANIC CHEMICAL INDUSTRY LTD.)

### (Color Developer)

LCV: Leuco crystal violet (manufactured by Yamada Chemical Co., Ltd.)

TABLE 1

| Photosensitive resin composition | | P1 | P2 | P3 |
|---|---|---|---|---|
| Binder polymer | A-1 | 116 | — | 116 |
| | A-2 | — | 116 | — |
| Photopolymerizable | FA-321M | 28 | 35 | 28 |
| compound | FA-024M | 5 | 2 | 5 |
| | BPE-200 | 10 | — | 10 |
| | BP-2EM | — | 6 | — |
| Photopolymerization | B-CIM | 2.9 | 5.5 | 2.9 |
| initiator | | | | |
| Sensitizer | EAB | 0.08 | — | — |
| | PZ-501D | — | 0.027 | — |
| | Cumarin 102 | — | — | 0.08 |
| Polymerization inhibitor | TBC | 0.02 | 0.04 | 0.02 |
| | LA-7RD | — | 0.01 | — |
| Dye | MKG | 0.05 | 0.05 | 0.05 |
| Color developer | LCV | 0.3 | 0.77 | 0.3 |
| Solvent | Methanol | 5 | 6 | 5 |
| | Acetone | 5 | 16 | 9 |
| | Toluene | 9 | 10 | 5 |

### [Support Film]

As the support film of the photosensitive element, the following PET films were prepared.
S1: Biaxially oriented PET film with a three-layer structure (thickness: 16 μm)
S2: Biaxially oriented PET film with a three-layer structure (thickness: 16 μm)
S3: Biaxially oriented PET film with a three-layer structure (manufactured by Toray Industries, Inc., trade name “FB-40”, thickness: 16 μm)
S4: Biaxially oriented PET film with a three-layer structure (manufactured by Toray Industries, Inc., trade name “FS-31”, thickness: 16 μm)
S5: Biaxially oriented PET film with a three-layer structure (manufactured by Toray Industries, Inc., trade name “QS-63”, thickness: 16 μm)

The number of lubricants contained in a 0.0225 mm² (0.150 mm×0.150 mm) area in the first surface of the support film was measured using a confocal microscope (manufactured by Lasertec Corporation, trade name “Hybrid laser microscope OPTELICS HYBRID”). An image was acquired at a lens numerical aperture (Na) of 0.8, a magnification of 50 times, and a digital zooming of 2 times and under the conditions of Table 2 below, and the size and number of lubricants were calculated from pixels in the image. The results are shown in Table 3.

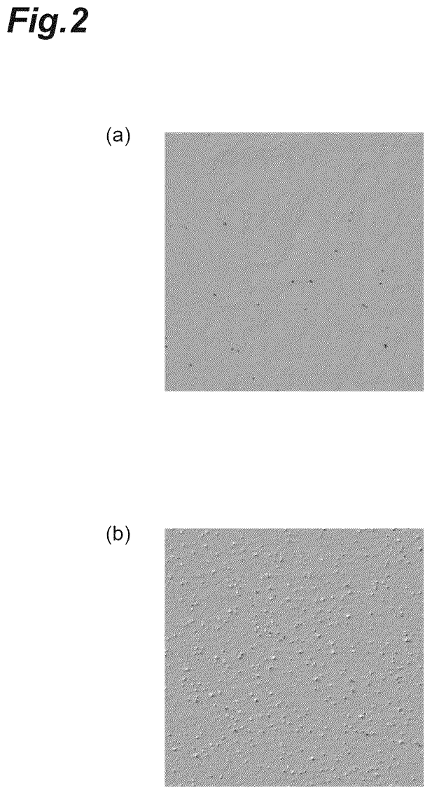

An image (magnification: 600 times) obtained by observing the surface of the support film (S1) of Example 1 is shown in (a) in FIG. 2, and an image (magnification: 600 times) obtained by observing the surface of the support film (S3) of Comparative Example 1 is shown in (b) in FIG. 2. Scales in the images of (a) and (b) in FIG. 2 are the same as each other.

TABLE 2

| Name | Item | Setting |
|---|---|---|
| Objective lens | TU Apo50x | ON |
| Nomarski prism | MBH 63200 | ON |
| Surface observation | Differential | ON |
| mode | interference mode | |
| Autofocus | Setting of Ref position | Checked |
| Image acquisition | Confocal | ON |
| condition setting | CCD mode | Green |
| | Scanning rate/image size | Standard/1024 × 1024 |
| | HDR | OFF |
| | Zoom | 200% |
| | Brightness | 700 (adjustment item) |
| | Exposure time | 4 |
| Surface shape | UP position | 3 |
| | LOW position | −3 |
| | Scanning time | 10 sec |
| | Scanning resolution | 0.17 |
| | Algorithm | MaxPeak |
| Image processing | Target image | Luminance |
| | Spline (highpass) | X: 140 Y: 140 um |
| | Brightness | 2 |
| | Contrast | 2 |
| Shape property | Creation method for | Binarization of |
| | two images | brightness image |
| | Threshold setting | Auto |
| | Automatic threshold | Histogram peak method |
| | algorithm | |
| | Effective region | Up |
| | Display format | Gradation value |
| | Histogram peak setting | Up |
| | | 30 |

The support film was cut into a size of 4 mm×25 mm such that the TD (Transverse direction) direction of the support film was the longitudinal direction, thereby obtaining a test piece. The test piece was set in a thermomechanical analyzer (manufactured by Hitachi High-Tech Science Corporation, trade name “TMA7100 Type”) with a distance between chucks of 10 mm, and the linear expansion coefficient of the test piece was measured under the conditions of a tension mode, a temperature range of 20 to 200° C., and a temperature increase rate of 5° C./min. From the measurement results, CTE (α1) at 80 to 115° C. and CTE (α2) at 115 to 130° C. were obtained. The results are shown in Table 3.

TABLE 3

| | S1 | S2 | S3 | S4 | S5 |
|---|---|---|---|---|---|
| Maximum particle size (μm) of | 0.9 | 1.2 | 1.8 | 1.5 | 1.5 |
| lubricant | | | | | |
| Number of lubricants of 1.0 μm | 0 | 3 | 43 | 14 | 13 |
| or more | | | | | |
| Number of lubricants of less than | 30 | 127 | 408 | 79 | 65 |
| 1.0 μm | | | | | |
| α1 (ppm/° C.) | 117 | 105 | 105 | 112 | 113 |
| α2 (ppm/° C.) | 93 | 62 | −65 | −7 | −2 |

### [Photosensitive Element]

A solution of the photosensitive resin composition was applied uniformly on the first layer of the support film using a comma coater. Subsequently, the solution was dried for 2 minutes with a hot air convection drier at 100° C. to form a photosensitive layer having a thickness of 15 μm. Next, a PE film (manufactured by TAMAPOLY CO., LTD., trade name “NF-15A”, thickness: 28 μm) as the protective film was laminated on the photosensitive layer to produce a photosensitive element.

### [Evaluation]

### (Production of Laminate)

Both surfaces of an interlayer insulating material (manufactured by Ajinomoto Fine-Techno Co., Inc., trade name “GX-T31”) was subjected to non-electrolytic plating to form a copper layer (electroless copper, thickness: 500 nm), and then the surface of the copper layer was pickled, rinsed, and dried (with an air stream) to obtain a substrate a. This substrate a was heated to 80° C., and then the photosensitive element was laminated such that the photosensitive layer was in contact with the copper layer while peeling off the protective film of the above-described photosensitive element. As such, a laminate including the substrate a, the photosensitive layer, and the support film in the lamination direction in this order was obtained. The lamination was performed using a heat roll set at 110° C. at a pressure-bonding pressure of 0.4 Pa and at a roll speed of 1.5 m/min.

### (Adhesiveness and Resolution)

The photosensitive layer of the above-described laminate was exposed with an irradiation energy dose for 11 steps remaining after development of a 41-step tablet, using a high-resolution projection-type exposure apparatus (manufactured by Ushio Inc., trade name “UX-2240”) having a phototool with a 41-step tablet, a glass chromium-type phototool having a wiring pattern with a line width/space width of 2/6 to 20/90 (unit: μm) as a negative for evaluation of adhesiveness, a glass chromium-type phototool having a wiring pattern with a line width/space width of 2/2 to 20/20 (unit: μm) as a negative for evaluation of resolution, and a high-pressure mercury lamp. Next, the support film was peeled off, and a 10% by mass sodium carbonate aqueous solution was spray-developed at 30° C. for a period of two times the minimum developing time to remove the unexposed area. Herein, the adhesiveness was evaluated on the basis of the smallest value (unit: μm) of the line widths that could been clearly formed by the development treatment. The resolution was evaluated on the basis of the smallest value (unit: μm) of the space widths between the line portions where the unexposed area could been clearly removed by the development treatment. The results are shown in Table 4.

(Number of Defects of Resist) A resist line (L/S=10/10 μm) of the laminate used in the above-described evaluation of resolution was observed (magnification: 500 times) randomly at ten places using a scanning electron microscope (manufactured by Hitachi, Ltd., trade name “SU-1500”), and the number of resist defects of 0.5 μm or more was evaluated. Converted values obtained by converting average values of the number of defects into the number per 81 cm² are shown in Table 4.

TABLE 4

| | | | | | Comparative | | |
|---|---|---|---|---|---|---|---|
| | Example | | | | Example | | |
| | 1 | 2 | 3 | 4 | 1 | 2 | 3 |
| Support film | S1 | S1 | S1 | S2 | S3 | S4 | S5 |
| Photosensitive layer | P1 | P2 | P3 | P1 | P1 | P1 | P1 |
| Adhesiveness (μm) | 6 | 4.5 | 8 | 6 | 6 | 6 | 6 |
| Resolution (μm) | 6 | 5 | 8 | 6 | 7 | 6 | 6 |
| Number of defects of resist | 1 | 1 | 1 | 1 | 15 | 7 | 6 |

### REFERENCE SIGNS LIST

1: photosensitive element, 10: support film, 10a: first surface, 10b: second surface, 20: photosensitive layer.

1. A photosensitive element comprising: a support film containing a lubricant; and a photosensitive layer formed on a first surface of the support film,
wherein a number of lubricants having a particle size of 1.0 μm or more contained in the first surface of the support film is 10 or less per 0.0225 mm².

2. The photosensitive element according to claim 1, wherein a number of lubricants having a particle size of less than 1.0 μm contained in the first surface is 10 to 160 per 0.0225 mm².

3. The photosensitive element according to claim 1, wherein a linear expansion coefficient of the support film at 80 to 115° C. is 30 to 170 ppm/° C., and a linear expansion coefficient of the support film at 115 to 130° C. is 30 to 170 ppm/° C.

4. The photosensitive element according to claim 1, wherein the support film has a polyester film and a lubricant layer disposed on at least one surface of the polyester film.

5. The photosensitive element according to claim 4, wherein the support film is a biaxially oriented polyester film with a three-layer structure.

6. The photosensitive element according to claim 1, wherein the support film does not contain a lubricant having a particle size of more than 3.0 μm.

7. A method for forming a resist pattern, the method comprising:
a lamination step of laminating the photosensitive element according to claim 1 on a substrate in order of the photosensitive layer and the support film;
an exposure step of irradiating a predetermined part of the photosensitive layer with an active light ray through the support film to form a photo-cured area; and
a development step of removing an area other than the photo-cured area in the photosensitive layer.

8. A method for producing a printed wiring board, the method comprising a step of subjecting a substrate having a resist pattern formed by the method for forming a resist pattern according to claim 7 to an etching treatment or a plating treatment to form a conductor pattern.
